(19) United States
(12) Patent Application Publication
(10) Pub. No.: US 2025/0193998 A1
(43) Pub. Date: Jun. 12, 2025

(54) ELECTRONIC DEVICE

(71) Applicant: Innolux Corporation, Miaoli County (TW)

(72) Inventors: Ying-Jen Chen, Miaoli County (TW); Yan-Zheng Wu, Miaoli County (TW)

(73) Assignee: Innolux Corporation, Miaoli County (TW)

(21) Appl. No.: 18/943,827

(22) Filed: Nov. 11, 2024

Related U.S. Application Data
(60) Provisional application No. 63/606,606, filed on Dec. 6, 2023.

(30) Foreign Application Priority Data
Aug. 23, 2024 (CN) 202411168562.7

(51) Int. Cl. H05K 1/02; H03H 7/38

(52) U.S. Cl. CPC H05K 1/0243; H03H 7/38; H05K 2201/10098

(57) ABSTRACT

An electronic device is provided. The electronic device includes a substrate, a radio frequency (RF) element, an electronic element, a coupler, a detector, a controller, and an impedance matching circuit. The RF element, the electronic element, the coupler, the detector, and the impedance matching circuits are arranged on the substrate. The coupler generates a first coupling output signal in response to a first input coupling signal and a second coupling output signal in response to a second input coupled signal. The detector generates a determination signal based on the first coupling output signal and the second coupling output signal. The controller is arranged outside the substrate and generates a control signal according to the determination signal. The impedance matching circuit provides an impedance for a transmission path between the RF element and the electronic element in response to the control signal.

### CROSS-REFERENCE TO RELATED APPLICATION

This application claims the priority benefit of U.S. provisional application Ser. No. 63/606,606, filed on Dec. 6, 2023 and China patent application serial no. 202411168562.7, filed on Aug. 23, 2024. The entirety of each of the above-mentioned patent applications is hereby incorporated by reference herein and made a part of this specification.

### BACKGROUND

### Technical Field

The disclosure relates to an electronic device; more particularly, the disclosure relates to an electronic device including a radio frequency (RF) element.

### Description of Related Art

In general, due to variations in manufacturing processes and locations, impedance mismatch issues may arise among multiple transmission paths between various elements in an electronic device. For instance, the electronic device may be an antenna device, where the transmission paths between different or identical elements in the antenna device (such as between an antenna element and a RF element, between a power divider and a RF element, between two power dividers, and so on) may exhibit differing impedance mismatches (i.e., disparities between output impedance and input impedance), resulting in inconsistencies in RF signal amplitudes and/or phases at various locations in the antenna device. Larger impedance mismatches lead to increased reflection of RF signals within the transmission path, thereby adversely affecting the performance of the antenna device.

### SUMMARY

The disclosure provides an electronic device that may be configured to perform impedance matching for a transmission path between an electronic element and a radio frequency (RF) element.

According to an embodiment of the disclosure, an electronic device includes a substrate, a RF element, a first electronic element, a first coupler, a detector, a controller, and a first impedance matching circuit. The RF element is arranged on the substrate. The first electronic element is arranged on the substrate and electrically connected to the RF element. The first coupler is arranged on the substrate. The first coupler receives a first coupling output signal generated by the RF element in response to a first input coupling signal and receives a second coupling output signal generated by the first electronic element in response to a second input coupling signal. The detector is arranged on the substrate. The detector is electrically connected to the first coupler. The detector generates a determination signal according to the first coupling output signal and the second coupling output signal. The controller is arranged outside the substrate and electrically connected to the detector. The controller generates a control signal according to the determination signal. The first impedance matching circuit is arranged on the substrate and electrically connected to the controller. The first impedance matching circuit provides an impedance for the transmission path between the RF element and the first electronic element in response to the control signal.

Based on the above, the electronic device provided in one or more embodiments of the disclosure generates the determination signal according to the first coupling output signal and the second coupling output signal and generates the control signal according to the determination signal. Therefore, the first impedance matching circuit provides the impedance for the transmission path between the RF element and the first electronic element in response to the control signal. As a result, the impedance for the transmission path between the RF element and the first electronic element may be matched.

### BRIEF DESCRIPTION OF THE DRAWINGS

FIG. 1 is a schematic diagram illustrating an electronic device according to an embodiment of the disclosure.

FIG. 2 is a schematic diagram illustrating the distribution of a RF element and a plurality of electronic elements.

FIG. 3 is a schematic diagram illustrating an impedance matching circuit according to an embodiment of the disclosure.

FIG. 4 is a schematic diagram illustrating an impedance matching circuit according to an embodiment of the disclosure.

FIG. 5 is a schematic diagram illustrating an impedance matching circuit according to an embodiment of the disclosure.

FIG. 6 is a schematic diagram illustrating an electronic device according to an embodiment of the disclosure.

FIG. 7 is a flowchart illustrating an operation process according to an embodiment of the disclosure.

FIG. 8 is a schematic diagram illustrating an electronic device according to an embodiment of the disclosure.

FIG. 9 is a schematic diagram illustrating an electronic element, an impedance matching circuit, and a switch element according to an embodiment of the disclosure.

FIG. 10 is a schematic diagram illustrating an electronic element, an impedance matching circuit, and a switch element according to an embodiment of the disclosure.

### DESCRIPTION OF THE EMBODIMENTS

The disclosure may be understood with reference to the following detailed description with the drawings. Note that for clarity of description and ease of understanding, the drawings of the disclosure show a part of an electronic device, and certain elements in the drawings may not be drawn to scale. In addition, the number and size of each device shown in the drawings serve for exemplifying instead of limiting the scope of the disclosure.

Certain terminologies are used throughout the description and the appended claims to refer to specific elements. As to be understood by those skilled in the art, electronic device manufacturers may refer to an element by different names. Herein, it is not intended to distinguish between elements that have different names instead of different functions. In the following description and claims, terminologies such as “include”, “comprise”, and “have” are used in an open-ended manner, and thus should be interpreted as “including, but not limited to”. Therefore, the terminologies “include”, “comprise”, and/or “have” used in the description of the disclosure denote the presence of corresponding features, regions, steps, operations, and/or elements but are not limited to the presence of one or more corresponding features, regions, steps, operations, and/or elements.

It should be understood that when one element is referred to as being “coupled to”, “connected to”, or “conducted to” another element, the one element may be directly connected to the another element with electrical connection established, or intervening elements may also be present in between these elements for electrical interconnection (indirect electrical connection). Comparatively, when one element is referred to as being “directly coupled to”, “directly conducted to”, or “directly connected to” another element, no intervening elements are present in between.

Although terminologies such as first, second, and third may be used to describe different diverse constituent elements, such constituent elements are not limited by the terminologies. The terminologies are used to discriminate one constituent element from other constituent elements in the description. In the claims, the terminologies first, second, third, and so on may be used in accordance with the order of claiming elements instead of using the same terminologies. Accordingly, a first constituent element in the following description may be a second constituent element in the claims.

The electronic device provided in the disclosure may include but is not limited to a display device, an antenna device, a sensing device, a light-emitting device, a touch display, a curved display, or a free-shape display. The electronic device may include a bendable or flexible electronic device. The electronic device may include, for instance, liquid crystal, light emitting diode (LED), quantum dot (QD), fluorescence, phosphor, other suitable display media, or a combination thereof, which should however not be construed as a limitation in the disclosure. The LED may include, for instance, an organic light-emitting diode (OLED), a mini LED, a micro LED, a quantum dot LED (including QLED and QDLED), other suitable materials, or a combination thereof, which should however not be construed as a limitation in the disclosure. The display device may, for instance, include a tiled display device, which should however not be construed as a limitation in the disclosure. The antenna device may, for instance, include a liquid crystal antenna, a tiled antenna device, or a phased RF device, which should however not be construed as a limitation in the disclosure. It should be noted that the electronic device may be any combination of the above, which should however not be construed as a limitation in the disclosure. In addition, the shape of the electronic device tiled be rectangular, circular, polygonal, a shape with curved edges, or other appropriate shapes. The electronic device may have peripheral systems, such as a driving system, a control system, a light source system, and the like, so as to support a display device, an antenna device, or a splicing device, which should however not be construed as a limitation in the disclosure. The detection device may include a camera, an infrared sensor, a fingerprint sensor, and so on, which should not be construed as a limitation in the disclosure. In some embodiments, the detection device may further include a flashlight, an infrared (IR) light source, other sensors, electronic elements, or a combination of the foregoing, which should not be construed as a limitation in the disclosure.

Note that features in different embodiments described below may be replaced, recombined, or mixed with each other to form another embodiment without departing from the spirit of the disclosure.

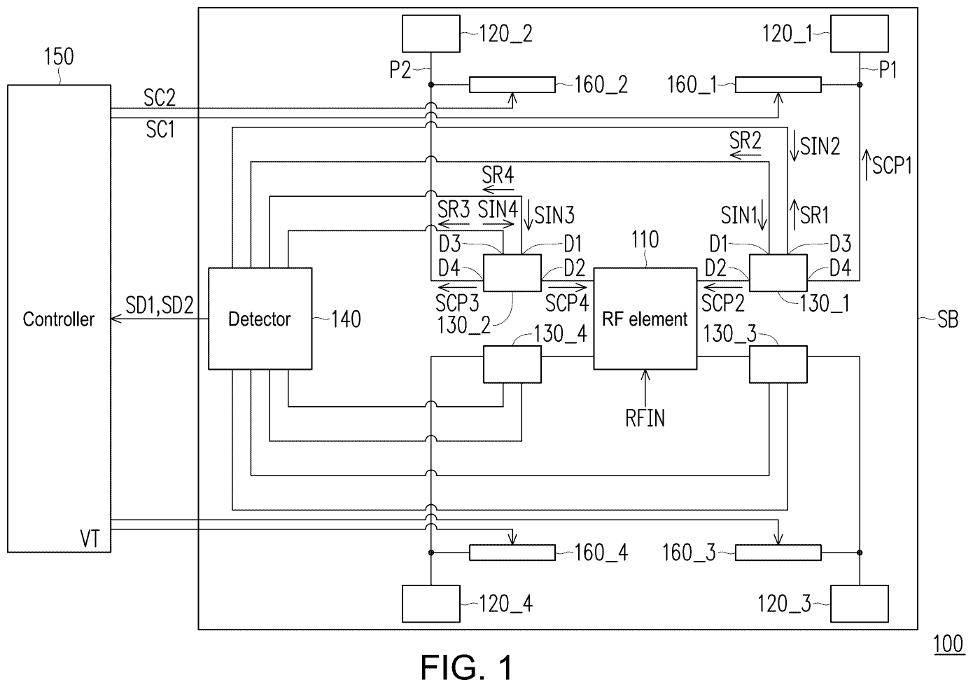

Please refer to FIG. 1, which is a schematic diagram illustrating an electronic device according to an embodiment of the disclosure. In this embodiment, the electronic device 100 includes a substrate SB, a radio frequency (RF) element 110, electronic elements 120_1 to 120_4, couplers 130_1 to 130_4, a detector 140, a controller 150, and impedance matching circuits 160_1 to 160_4. The RF element 110, the electronic elements 120_1 to 120_4, the couplers 130_1 to 130_4, the detector 140, and the impedance matching circuits 160_1 to 160_4 are arranged on the substrate SB. The controller 150 is arranged outside the substrate SB. The electronic elements 120_1 to 120_4 are electrically connected to the RF element 110. The couplers 130_1 to 130_4 are electrically connected to the detector 140. The couplers 130_1 to 130_4 are electrically connected to the electronic elements 120_1 to 120_4 in a one-to-one manner. For instance, the coupler 130_1 is electrically connected to electronic element 120_1, the coupler 130_2 is electrically connected to electronic element 120_2, and the rest may be deduced therefrom. The controller 150 is electrically connected to the detector 140 and the impedance matching circuits 160_1 to 160_4.

The impedance matching circuit 160_1 is electrically connected to a transmission path P1 between the RF element 110 and the electronic element 120_1, the impedance matching circuit 160_2 is electrically connected to a transmission path P2 between the RF element 110 and the electronic element 120_2, and the rest may be deduced therefrom. Taking the coupler 130_1 as an example, the coupler 130_1 is electrically connected to the electronic element 120_1. The coupler 130_1 generates a first coupling output signal SR1 in response to a first input coupling signal SIN1. The coupler 130_1 generates a second coupling output signal SR2 in response to a second input coupling signal SIN2. The detector 140 receives the first coupling output signal SR1 and the second coupling output signal SR2 from the coupler 130_1. The detector 140 generates a first determination signal SD1 according to the first coupling output signal SR1 and the second coupling output signal SR2. The controller 150 generates a first control signal SC1 according to the first determination signal SD1. The impedance matching circuit 160_1 provides impedance to the transmission path P1 between the RF element 110 and the electronic element 120_1 in response to the control signal SC1.

It is worth mentioning that the first coupling output signal SR1 and the second coupling output signal SR2 may be associated with the path impedance between the electronic element 120_1 and the coupler 130_1 and the path impedance between the RF element 110 and the coupler 130_1. The electronic device 100 generates the first determination signal SD1 according to the first coupling output signal SR1 and the second coupling output signal SR2 and generates the control signal SC1 according to the first determination signal SD1. Therefore, the impedance matching circuit 160_1 may provide impedance to the transmission path P1 between the RF element 110 and the electronic element 120_1 in response to the first control signal SC1. As a result, based on the first coupling output signal SR1 and the second coupling output signal SR2, the impedance for the transmission path P1 between the RF element 110 and the electronic element 120_1 may be matched.

In this embodiment, the RF element 110 may receive a radio frequency (RF) input signal RFIN. The RF element 110 modulates the RF input signal RFIN and provides the modulated RF input signal to the electronic elements 120_1 and 120_2. For instance, the RF element 110 may adjust at least one of the amplitude, the frequency, and the phase of the RF input signal RFIN.

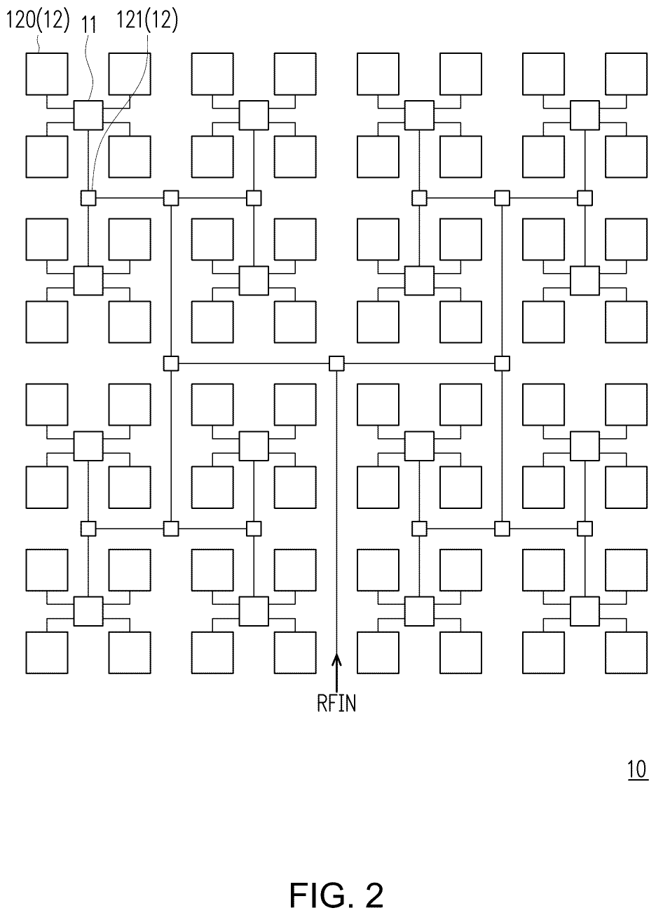

Please refer to FIG. 1 and FIG. 2. FIG. 2 is a schematic diagram illustrating the distribution of a RF element and a plurality of electronic elements. The electronic device 10 in FIG. 2 may be applicable in the matching operation in FIG. 1. The electronic elements 120_1 to 120_4 in FIG. 1 may be, for instance, one of the electronic elements 12 in FIG. 2 (such as the antenna element 120 and the power divider 121), which should not be construed as a limitation in the disclosure. It should be noted that there will be impedance differences (i.e., differences between the output impedance and the input impedance) in the transmission paths between the electronic elements 12 located at different positions and the RF elements 11, or in the transmission paths between the electronic elements 12. In the electronic device 10, the greater the impedance difference, the greater the reflected signal generated by the RF signal in the transmission path. In this embodiment, the impedance matching circuits 160_1 to 160_4 provide impedance to the transmission paths to reduce the impedance differences in the transmission paths, so that the electronic device may achieve favorable performance.

In some embodiments, the electronic element includes active elements and passive elements on the transmission path, e.g., chips, diodes, transistors, etc. The controller 150 may be, for instance, a central processing unit (CPU) or other programmable general-purpose or special-purpose microprocessors, digital signal processors (DSP), programmable controllers, application specific integrated circuits (ASIC), programmable logic devices (PLD), or other similar devices, or combinations of these devices, which may load and execute computer programs.

In this embodiment, the coupler 130_1 includes connection points D1 to D4. During a first matching period, the detector 140 may provide the first input coupling signal SIN1. During the first matching period, the coupler 130_1 receives the first input coupling signal SIN1 through the connection point D1. The coupler 130_1 performs current dividing on the first input coupling signal SIN1 to generate the first coupling output signal SR1 and a coupling signal SCP1. The coupler 130_1 provides the first coupling output signal SR1 to the detector 140 through the connection point D3. The coupler 130_1 provides the coupling signal SCP1 to the electronic element 120_1 through the connection point D4. A current dividing ratio of the first coupling output signal SR1 to the coupling signal SCP1 is determined according to the impedance ratio at the connection points D3 and D4 of the coupler 130_1. Therefore, during the first matching period, the numerical value of the first coupling output signal SR1 may reflect the impedance ratio at the connection points D3 and D4 of the coupler 130_1.

During a second matching period, the detector 140 may provide the second input coupling signal SIN2. The first input coupling signal SIN1 is identical to the second input coupling signal SIN2. During the second matching period, the coupler 130_1 receives the second input coupling signal SIN2 through the connection point D3. The coupler 130_1 performs current dividing on the first input coupling signal SIN2 to generate the second coupling output signal SR2 and a coupling signal SCP2. The coupler 130_1 provides the first coupling output signal SR1 to the detector 140 through the connection point D1. The coupler 130_1 provides the coupling signal SCP2 to the RF element 110 through the connection point D2. A current dividing ratio of the second coupling output signal SR2 to the coupling signal SCP2 is determined according to the impedance ratio at the connection points D1 and D2 of the coupler 130_1. Therefore, during the second matching period, the numerical value of the second coupling output signal SR2 may reflect the impedance ratio at the connection points D1 and D2 of the coupler 130_1.

The first matching period is different from the second matching period. For instance, the first matching period may be earlier than the second matching period. For instance, the first matching period may be later than the second matching period. The coupler 130_1 may control the connections among the connection points D1 to D4. During the first matching period, the coupler 130_1 may connect the connection points D1, D3, and D4 together. During the second matching period, the coupler 130_1 may connect the connection points D1, D2, and D3 together. During a normal operation period, the coupler 130_1 may connect the connection points D2 and D4 together.

In this embodiment, the detector 140 generates the first determination signal SD1 according to the degree of difference between the first coupling output signal SR1 and the second coupling output signal SR2. The degree of difference may be, for instance, a difference value between the first coupling output signal SR1 and the second coupling output signal SR2 (SR1−SR2), a difference value between the second coupling output signal SR2 and the first coupling output signal SR1 (SR2−SR1), a ratio of the first coupling output signal SR1 to the second coupling output signal SR2 (SR1/SR2), or a ratio of the second coupling output signal SR2 to the first coupling output signal SR1 (SR2/SR1), which should not be construed as a limitation in the disclosure. For instance, at a frequency (e.g., a frequency at the center of the electronic device/the antenna device), the detector 140 may generate the first determination signal SD1 according to at least one numerical value of the degree of an amplitude difference, the degree of a voltage difference, and the degree of a phase difference between the first coupling output signal SR1 and the second coupling output signal SR2. The controller 150 receives the first determination signal SD1 and determines the first determination signal SD1. When the first determination signal SD1 indicates that the degree of difference between the first coupling output signal SR1 and the second coupling output signal SR2 is greater than or equal to a threshold value VT, it indicates that the impedance for the transmission path P1 between the RF element 110 and the electronic element 120_1 is apparently mismatched (i.e., the input impedance of the electronic element 120_1 is apparently different from the output impedance of the electronic element 120_1). Therefore, the controller 150 changes the first control signal SC1, causing the first impedance matching circuit 160_1 to change the impedance for the transmission path P1 between the RF element 110 and the electronic element 120_1 according to the first control signal SC1.

On the other hand, when the first determination signal SD1 indicates that the degree of difference between the first coupling output signal SR1 and the second coupling output signal SR2 is less than the threshold value VT, it indicates that the impedance for the transmission path P1 between the RF element 110 and the electronic element 120_1 is matched (i.e., the input impedance of the electronic element 120_1 is apparently the same as or close to the output impedance of the electronic element 120_1). Therefore, the controller 150 does not change the first control signal SC1.

Taking the coupler 130_2 as an example, the coupler 130_2 is electrically connected to the electronic element 120_2. The coupler 130_2 generates a third coupling output signal SR3 in response to a third input coupling signal SIN3. The coupler 130_1 generates a fourth coupling output signal SR4 in response to a fourth input coupling signal SIN4. The detector 140 receives the third coupling output signal SR3 and the fourth coupling output signal SR4 from the coupler 130_1. The detector 140 generates a second determination signal SD2 according to the third coupling output signal SR3 and the fourth coupling output signal SR4. The controller 150 generates a second control signal SC2 according to the second determination signal SD2. The impedance matching circuit 160_2 provides the impedance for the transmission path P2 between the RF element 110 and the electronic element 120_2 in response to the second control signal SC2.

In this embodiment, similar to the coupler 130_1, the coupler 130_2 includes the connection points D1 to D4. During a third matching period, the detector 140 may provide the third input coupling signal SIN3. During the third matching period, the coupler 130_2 receives the third input coupling signal SIN3 through the connection point D1. The coupler 130_2 performs current dividing on the first input coupling signal SIN3 to generate the third coupling output signal SR3 and a coupling signal SCP3. The coupler 130_2 provides the first coupling output signal SR3 to the detector 140 through the connection point D3. The coupler 130_2 provides the coupling signal SCP3 to the electronic element 120_2 through the connection point D4. A current dividing ratio of the third coupling output signal SR3 to the coupling signal

SCP3 is determined according to the impedance ratio at the connection points D3 and D4 of the coupler 130_2. Therefore, during the third matching period, the numerical value of the third coupling output signal SR3 may reflect the impedance ratio at the connection points D3 and D4 of the coupler 130_2.

During a fourth matching period, the detector 140 may provide the fourth input coupling signal SIN4. The third input coupling signal SIN3 is the same as the fourth input coupling signal SIN4. During the fourth matching period, the coupler 130_1 performs current dividing on the fourth input coupling signal SIN4 to generate the fourth coupling output signal SR4 and a coupling signal SCP4. The coupler 130_2 provides the fourth coupling output signal SR4 to the detector 140 through the connection point D1. The coupler 130_2 provides the coupling signal SCP4 to the RF element 110 through the connection point D2. A current dividing ratio of the fourth coupling output signal SR4 to the coupling signal SCP4 is determined according to the impedance ratio at the connection points D1 and D2 of the coupler 130_2. Therefore, during the fourth matching period, the numerical value of the fourth coupling output signal SR4 may reflect the impedance ratio at the connection points D1 and D2 of the coupler 130_2.

The third matching period is different from the fourth matching period. For instance, the third matching period may be earlier than the fourth matching period. For instance, the third matching period may be later than the fourth matching period. Moreover, the third matching period may be the same as or different from the first matching period. The fourth matching period may be the same as or different from the second matching period.

The coupler 130_2 may control the connections among the connection points D1 to D4. During the third matching period, the coupler 130_2 may connect the connection points D1, D3, and D4 together. During the fourth matching period, the coupler 130_2 may connect the connection points D1, D2, and D3 together. During the normal operation period, the coupler 130_2 may connect the connection points D2 and D4 together.

In this embodiment, the detector 140 generates the second determination signal SD2 according to the degree of difference between the third coupling output signal SR3 and the fourth coupling output signal SR4. The degree of difference may be, for instance, a difference value between the third coupling output signal SR3 and the fourth coupling output signal SR4 (SR3−SR4), a difference value between the fourth coupling output signal SR4 and the third coupling output signal SR3 (SR4−SR3), a ratio of the third coupling output signal SR3 to the fourth coupling output signal SR4 (SR3/SR4), or a ratio of the fourth coupling output signal SR4 to the third coupling output signal SR3 (SR4/SR3), which should not be construed as a limitation in the disclosure. For instance, at a frequency (e.g., a frequency at the center of the electronic device/the antenna device), the detector 140 may generate the second determination signal SD2 according to at least one numerical value of the degree of the amplitude difference, the degree of the voltage difference, and the degree of the phase difference between the third coupling output signal SR3 and the fourth coupling output signal SR4. The controller 150 also determines the second determination signal SD2. When the second determination signal SD2 indicates that the degree of difference between the third coupling output signal SR3 and the fourth coupling output signal SR4 is greater than the threshold value VT, it indicates that the impedance for the transmission path P2 between the RF element 110 and the electronic element 120_2 is apparently mismatched (i.e., the input impedance of the electronic element 120_2 is apparently different from the output impedance of the electronic element 120_2). Therefore, the controller 150 changes the second control signal SC2, causing the impedance matching circuit 160_2 to change the impedance for the transmission path P2 between the RF element 110 and the electronic element 120_2 according to the second control signal SC2.

On the other hand, when the first determination signal SD1 indicates that the degree of difference between the third coupling output signal SR3 and the fourth coupling output signal SR4 is less than or equal to the threshold value VT, it indicates that the impedance for the transmission path P2 between the RF element 110 and the electronic element 120_2 is matched (i.e., the input impedance of the electronic element 120_2 is apparently the same as or similar to the output impedance of the electronic element 120_2). Therefore, the controller 150 does not change the second control signal SC2.

In this embodiment, the first input coupling signal SIN1, the second input coupling signal SIN2, the third input coupling signal SIN3, the fourth input coupling signal SIN4, the first coupling output signal SR1, the second coupling output signal SR2, the third coupling output signal SR3, and the fourth coupling output signal SR4 are RF signals, respectively. The first control signal SC1 and the second control signal SC2 each include at least one direct current signal (e.g., a direct current voltage signal).

In this embodiment, operations of the couplers 130_3 and 130_4 and the impedance matching circuits 160_3 and 160_4 may be similar to operations of the couplers 130_1 and 130_2 and the impedance matching circuits 160_1 and 160_2 and thus will not be further elaborated hereinafter.

For the purpose of illustration, this embodiment is exemplified with one RF element 110, four electronic elements 120_1 to 120_4, four couplers 130_1 to 130_4, and one detector 140, which should not be considered as a limitation in the disclosure. In some embodiments, the number of the RF elements, the electronic elements, the couplers, and the detectors may be one or more.

In some embodiments, at least one of the impedance matching circuits 160_1 to 160_4 is electrically connected to the transmission path between two electronic elements. For instance, at least one of the impedance matching circuits 160_1 to 160_4 is electrically connected to the transmission path between two power dividers.

In this embodiment, the controller 150 is arranged outside the substrate SB. The controller 150 is electrically connected to the substrate SB through any form of chip on film (COF) in a packaging manner. In some embodiments, the controller 150 may be arranged on the substrate SB.

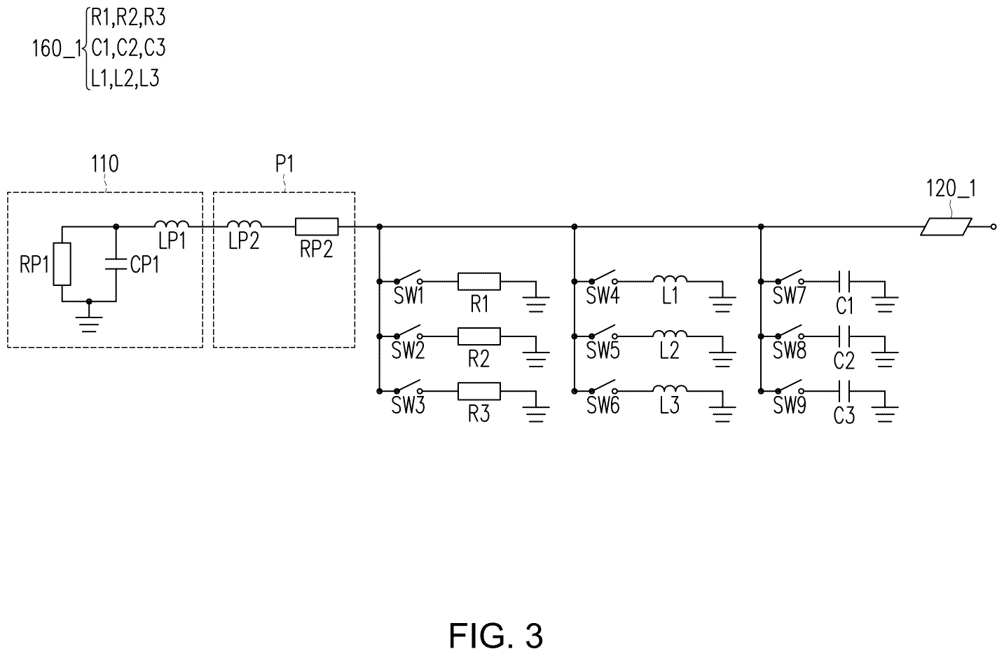

Please refer to FIG. 1 and FIG. 3. FIG. 3 is a schematic diagram illustrating an impedance matching circuit according to an embodiment of the disclosure. In this embodiment, the electronic device 100 further includes switch elements SW1 to SW9. The switch elements SW1 to SW9 are arranged on the substrate SB. In this embodiment, a first terminal of the impedance matching circuit 160_1 is electrically connected to the RF element 110 and the electronic element 120_1 through the switch elements SW1 to SW9. In other words, the first terminal of the impedance matching circuit 160_1 is electrically connected to the transmission path P1 between the RF element 110 and the electronic element 120_1 through the switch elements SW1 to SW9. A second terminal of the impedance matching circuit 160_1 is electrically connected to a reference low voltage (e.g., grounded).

In this embodiment, for instance, the impedance matching circuit 160_1 includes resistors R1 to R3, capacitors C1 to C3, and inductors L1 to L3. Resistances of the resistors R1 to R3 are different from one another. Capacitances of the capacitors C1 to C3 are different from one another. Inductances of the inductors L1 to L3 are different from one another. In other words, the impedance matching circuit 160_1 may provide a plurality of resistances, capacitances, and inductances. Besides, the number of the switch elements SW1 to SW9 that are turned on may determine different impedances used for impedance match in the transmission path P1.

A first terminal of the switch element SW1 is electrically connected to the transmission path P1. A control terminal of the switch element SW1 is coupled to the controller 150. The resistor R1 is electrically connected between a second terminal of the switch element SW1 and the reference low voltage. A first terminal of the switch element SW2 is electrically connected to the transmission path P1. A control terminal of the switch element SW2 is coupled to the controller 150. The resistor R2 is electrically connected between a second terminal of the switch element SW2 and the reference low voltage. A first terminal of the switch element SW3 is electrically connected to the transmission path P1. A control terminal of the switch element SW3 is coupled to the controller 150.

A first terminal of the switch element SW4 is electrically connected to the transmission path P1. A control terminal of the switch element SW4 is coupled to the controller 150. The inductor L1 is electrically connected between a second terminal of the switch element SW4 and the reference low voltage. A first terminal of the switch element SW5 is electrically connected to the transmission path P1. A control terminal of the switch element SW5 is coupled to the controller 150. The inductor L2 is electrically connected between a second terminal of the switch element SW5 and the reference low voltage. A first terminal of the switch element SW6 is electrically connected to the transmission path P1. A control terminal of the switch element SW6 is coupled to the controller 150. The inductor L3 is electrically connected between a second terminal of the switch element SW6 and the reference low voltage.

A first terminal of the switch element SW7 is electrically connected to the transmission path P1. A control terminal of the switch element SW7 is coupled to the controller 150. The capacitor C1 is electrically connected between a second terminal of the switch element SW7 and the reference low voltage. A first terminal of the switch element SW8 is electrically connected to the transmission path P1. A control terminal of the switch element

SW5 is coupled to the controller 150. The capacitor C2 is electrically connected between a second terminal of the switch element SW8 and the reference low voltage. A first terminal of the switch element SW9 is electrically connected to the transmission path P1. A control terminal of the switch element SW9 is coupled to the controller 150. The capacitor C3 is electrically connected between a second terminal of the switch element SW9 and the reference low voltage.

In this embodiment, the RF element 110 has an equivalent resistance RP1, an equivalent capacitance CP1, and an equivalent inductance LP1. The transmission path P1 has an equivalent resistance RP2 and an equivalent inductance LP2. It should be noted that, based on the manufacturing process of the RF element 110, a distance between the RF elements 110, and the design of the transmission path P1, at least one of the equivalent resistances RP1 and RP2, the equivalent capacitance CP1, and the equivalent inductances LP1 and LP2 may change. These changes may cause impedance mismatch in the transmission path P1. Therefore, the controller 150 may provide the first control signal SC1 according to the first determination signal SD1. The first control signal SC1 may include a switch control signal. The switch elements SW1 to SW9 may be turned on or turned off respectively according to the switch control signal (for instance, a direct current voltage signal). In other words, the switch elements SW1 to SW9 may determine whether to provide the impedance of at least one of the resistors R1 to R3, the capacitors C1 to C3, and the inductors L1 to L3 to the transmission path P1 according to the switch control signal, thereby changing the impedance for the transmission path P1.

In some embodiments, the switch elements SW1 to SW9 may be arranged in the impedance matching circuit 160_1.

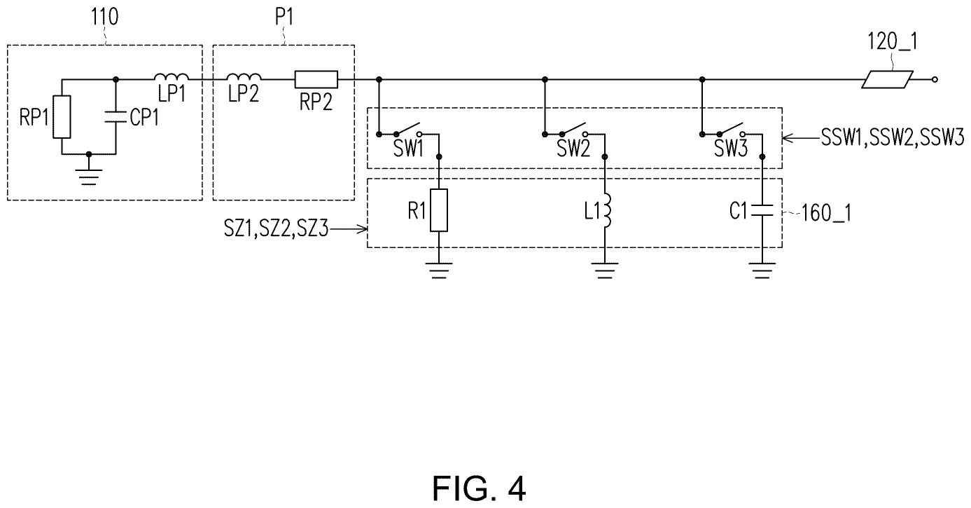

Please refer to FIG. 1 and FIG. 4. FIG. 4 is a schematic diagram illustrating an impedance matching circuit according to an embodiment of the disclosure. In this embodiment, the electronic device 100 further includes the switch elements SW1 to SW3. The switch elements SW1 to SW3 are arranged on the substrate SB. In this embodiment, the first terminal of the impedance matching circuit 160_1 is electrically connected to the RF element 110 and the electronic element 120_1 through the switch elements SW1 to SW3. In other words, the first terminal of the impedance matching circuit 160_1 is electrically connected to the transmission path P1 between the RF element 110 and the electronic element 120_1 through the switch elements SW1 to SW3. The second terminal of the impedance matching circuit 160_1 is electrically connected to the reference low voltage (e.g., grounded).

In this embodiment, for instance, the impedance matching circuit 160_1 includes the resistor R1, the capacitor C1, and the inductor L1. The resistor R1 is a variable resistor. The capacitor C1 is a variable capacitor. The inductor L1 is a variable inductor. The impedance matching circuit 160_1 changes at least one of the resistance, the capacitance, and the inductance of the impedance matching circuit 160_1 in response to the first control signal SC1.

The first terminal of the switch element SW1 is electrically connected to the transmission path P1. The control terminal of the switch element SW1 is coupled to the controller 150. The resistor R1 is electrically connected between the second terminal of the switch element SW1 and the reference low voltage. The first terminal of the switch element SW2 is electrically connected to the transmission path P1. The control terminal of the switch element SW2 is coupled to the controller 150. The inductor L1 is electrically connected between the second terminal of the switch element SW2 and the reference low voltage. The first terminal of the switch element SW3 is electrically connected to the transmission path P1. The control terminal of the switch element SW3 is coupled to the controller 150. The capacitor C1 is electrically connected between the second terminal of the switch element SW3 and the reference low voltage.

In this embodiment, the RF element 110 has the equivalent resistance RP1, the equivalent capacitance CP1, and the equivalent inductance LP1. The transmission path P1 has the equivalent resistance RP2 and the equivalent inductance LP2. Based on differences in the manufacturing process of the RF element 110, the distance between the RF elements 110, and the design of the transmission path P1, at least one of the equivalent resistances RP1 and RP2, the equivalent capacitance CP1, and the equivalent inductances LP1 and LP2 may change. These changes may cause impedance mismatch in the transmission path P1. Therefore, the controller 150 may provide the first control signal SC1 according to the first determination signal SD1. The first control signal SC1 includes switch control signals SSW1 to SSW3 and impedance control signals SZ1 to SZ3. The resistance of the resistor R1 may be adjusted based on the impedance control signal SZ1. The inductance of the inductor L1 may be adjusted based on the impedance control signal SZ2. The capacitance of the capacitor C1 may be adjusted based on the impedance control signal SZ3. Besides, the switch element SW1 may be turned on or turned off according to the switch control signal SSW1. The switch element SW2 may be turned on or turned off according to the switch control signal SSW2. The switch element SW3 may be turned on or turned off according to the switch control signal SSW3. Thus, the switch elements SW1 to SW3 may determine whether to provide at least one of the resistance of the resistor R1, the capacitance of the capacitor C1, and the inductance of the inductor L1 to the transmission path P1 according to the switch control signals SSW1 to SSW3, thereby changing the impedance for the transmission path P1.

In this embodiment, the switch control signals SSW1 to SSW3 and the impedance control signals SZ1 to SZ3 are respectively direct current signals (for instance, direct current voltage signals).

In some embodiments, the switch elements SW1 to SW3 may be arranged in the impedance matching circuit 160_1.

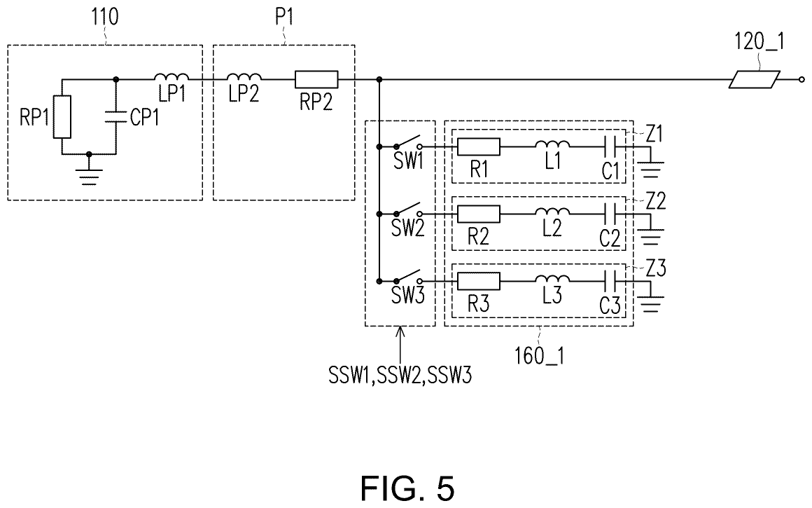

Please refer to FIG. 1 and FIG. 5. FIG. 5 is a schematic diagram illustrating an impedance matching circuit according to an embodiment of the disclosure. In this embodiment, the electronic device 100 further includes the switch elements SW1 to SW3. The switch elements SW1 to SW3 are arranged on the substrate SB. In this embodiment, the first terminal of the impedance matching circuit 160_1 is electrically connected to the RF element 110 and the electronic element 120_1 through the switch elements SW1 to SW3. In other words, the first terminal of the impedance matching circuit 160_1 is electrically connected to the transmission path P1 between the RF element 110 and the electronic element 120_1 through the switch elements SW1 to SW3. The second terminal of the impedance matching circuit 160_1 is electrically connected to the reference low voltage (e.g., grounded).

In this embodiment, for instance, the impedance matching circuit 160_1 includes the resistors R1 to R3, the capacitors C1 to C3, and the inductors L1 to L3. The resistor R1, the inductor L1, and the capacitor C1 are serially connected to one another to form an impedance string Z1. The resistor R2, the inductor L2, and the capacitor C2 are serially connected to one another to form an impedance string Z2. The resistor R3, the inductor L3, and the capacitor C3 are serially connected to one another to form an impedance string Z3. The number of the switch elements SW1 to SW3 that are turned on may determine different impedances used for impedance match in the transmission path P1.

The first terminal of the switch element SW1 is electrically connected to the transmission path P1. The control terminal of the switch element SW1 is coupled to the controller 150. The impedance string Z1 is electrically connected between the second terminal of the switch element SW1 and the reference low voltage. The first terminal of the switch element SW2 is electrically connected to the transmission path P1. The control terminal of the switch element SW2 is coupled to the controller 150. The impedance string Z2 is electrically connected between the second terminal of the switch element SW2 and the reference low voltage. The first terminal of the switch element SW3 is electrically connected to the transmission path P1. The control terminal of the switch element SW3 is coupled to the controller 150. The impedance string Z3 is electrically connected between the second terminal of the switch element SW3 and the reference low voltage.

In this embodiment, the RF element 110 has the equivalent resistance RP1, the equivalent capacitance CP1, and the equivalent inductance LP1. The transmission path P1 has the equivalent resistance RP2 and the equivalent inductance LP2. Based on differences in the manufacturing process of the RF element 110, the distance between the RF elements 110, and the design of the transmission path P1, at least one of the equivalent resistances RP1 and RP2, the equivalent capacitance CP1, and the equivalent inductances LP1, LP2 may change. These changes may cause impedance mismatch in the transmission path P1. Therefore, the controller 150 may provide the first control signal SC1 according to the first determination signal SD1. The switch elements SW1 to SW3 may determine whether to provide the impedance of at least one of the impedance strings Z1 to Z3 to the transmission path P1 according to the first control signal SC1, thereby changing the impedance for the transmission path P1.

In some embodiments, the switch elements SW1 to SW3 may be arranged in the impedance matching circuit 160_1.

In some embodiments, at least one of the impedance strings Z1 to Z3 may be replaced by a parallel impedance circuit of at least two of the resistor, the inductor, and the capacitor.

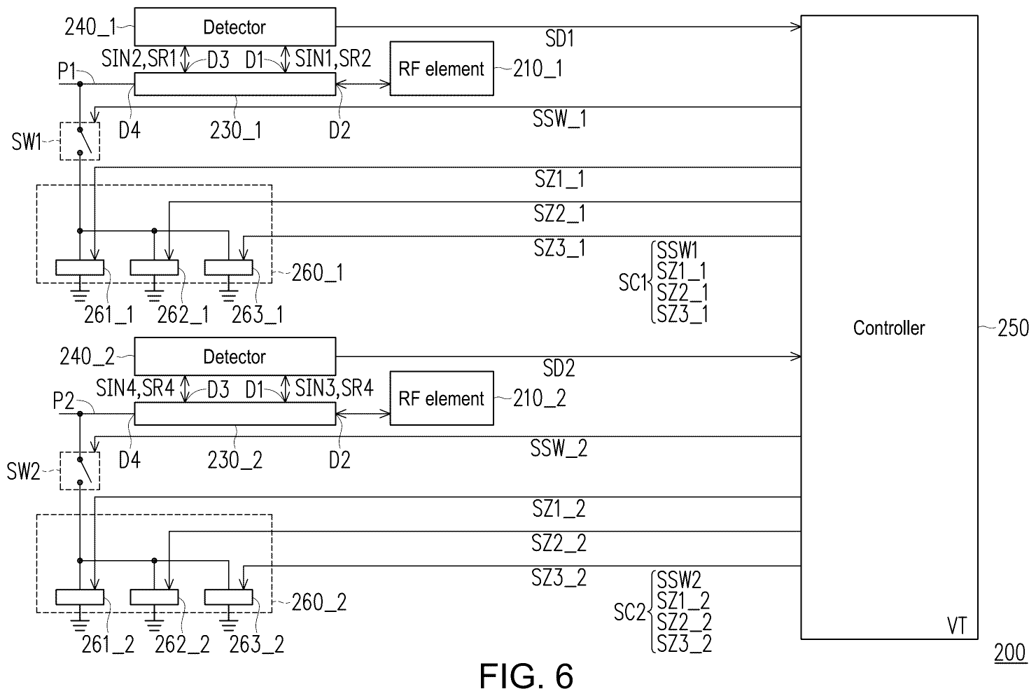

Please refer to FIG. 6. FIG. 6 is a schematic diagram illustrating an electronic device according to an embodiment of the disclosure. This embodiment demonstrates a partial circuit of an electronic device 200. In this embodiment, the electronic device 200 includes a substrate SB, RF elements 210_1 and 210_2, couplers 230_1 and 230_2, detectors 240_1 and 240_2, a controller 250, impedance matching circuits 260_1 and 260_2, and switch elements SW1 and SW2. The RF elements 210_1 and 210_2, the couplers 230_1 and 230_2, the detectors 240_1 and 240_2, the impedance matching circuits 260_1 and 260_2, and the switch elements SW1 and SW2 are respectively arranged on the substrate (e.g., the substrate SB shown in FIG. 1). The controller 250 is arranged outside the substrate SB.

In this embodiment, the coupler 230_1 includes the connection points D1 to D4. During the first matching period, the detector 240_1 provides the first input coupling signal SIN1. During the first matching period, the coupler 230_1 performs current dividing on the first input coupling signal SIN1 to generate the first coupling output signal SR1 and the coupling signal. The coupler 230_1 provides the first coupling output signal SR1 to the detector 240_1 through the connection point D3. The coupler 230_1 provides the coupling signal to the electronic element through the connection point D4. During the first matching period, the numerical value of the first coupling output signal SR1 may reflect the impedance ratio at the connection points D3 and D4 of the coupler 230_1.

During the second matching period, the detector 240_1 provides the second input coupling signal SIN2. The first input coupling signal SIN1 is the same as the second input coupling signal SIN2. During the second matching period, the coupler 230_1 receives the second input coupling signal SIN2 through the connection point D3. The coupler 230_1 performs current dividing on the first input coupling signal SIN2 to generate the second coupling output signal SR2 and the coupling signal. The coupler 230_1 provides the first coupling output signal SR1 to the detector 240_1 through the connection point D1. The coupler 230_1 provides the coupling signal to the RF element 210_1 through the connection point D2. During the second matching period, the numerical value of the second coupling output signal SR2 may reflect the impedance ratio at the connection points D1 and D2 of the coupler 230_1.

In this embodiment, the detector 240_1 generates the first determination signal SD1 according to the degree of difference between the first coupling output signal SR1 and the second coupling output signal SR2. The controller 250 determines the first determination signal SD1 to generate the first control signal SC1. The controller 250 applies the first control signal SC1 to change the impedance for the transmission path P1. The first control signal SC1 includes the switch control signal SSW1 and impedance control signals SZ1_1 to SZ3_1.

In this embodiment, the first terminal of the switch element SW1 is electrically connected to the transmission path P1. The control terminal of the switch element SW1 is coupled to the controller 250. The impedance matching circuit 260_1 includes variable impedance circuits 261_1 to 263_1. Each of the variable impedance circuits 261_1 to 263_1 includes at least one of a variable resistor, a variable capacitor, and a variable inductor. The variable impedance circuits 261_1 to 263_1 are respectively electrically connected between the second terminal of the switch element SW1 and the reference low voltage.

The switch element SW1 may be turned on or turned off according to the switch control signal SSW1. The variable impedance circuit 261_1 may adjust its impedance value according to the voltage value of the impedance control signal SZ1_1. The variable impedance circuit 262_1 may adjust its impedance value according to the voltage value of the impedance control signal SZ2_1. The variable impedance circuit 263_1 may adjust its impedance value according to the voltage value of the impedance control signal SZ3_1.

The coupler 230_2 includes the connection points D1 to D4. During the third matching period, the detector 240_2 provides the third input coupling signal SIN3. During the third matching period, the coupler 230_2 performs current dividing on the third input coupling signal SIN3 to generate the third coupling output signal SR3 and the coupling signal. The coupler 230_2 provides the first coupling output signal SR3 to the detector 240_2 through the connection point D3. The coupler 230_2 provides the coupling signal to the electronic element through the connection point D4. During the third matching period, the numerical value of the third coupling output signal SR3 may reflect the impedance ratio at the connection points D3 and D4 of the coupler 230_2.

During the fourth matching period, the detector 240_2 provides the fourth input coupling signal SIN4. The third input coupling signal SIN3 is the same as the fourth input coupling signal SIN4. During the fourth matching period, the coupler 230_2 performs current dividing on the fourth input coupling signal SIN4 to generate the fourth coupling output signal SR4 and the coupling signal. The coupler 230_2 provides the fourth coupling output signal SR4 to the detector 240_2 through the connection point D1. The coupler 230_2 provides the coupling signal to the RF element 210_2 through the connection point D2. The current dividing ratio of the fourth coupling output signal SR4 to the coupling signal is determined according to the impedance ratio at the connection points D1 and D2 of the coupler 230_2. During the fourth matching period, the numerical value of the fourth coupling output signal SR4 may reflect the impedance ratio at the connection points D1 and D2 of the coupler 230_2.

In this embodiment, the detector 240_2 generates the second determination signal SD2 according to the degree of difference between the third coupling output signal SR3 and the fourth coupling output signal SR4. The controller 250 determines the second determination signal SD2 to generate the second control signal SC2. The controller 250 applies the second control signal SC2 to change the impedance for the transmission path P2. The second control signal SC2 includes the switch control signal SSW2 and the impedance control signals SZ1_2 to SZ3_2.

In this embodiment, the first terminal of the switch element SW2 is electrically connected to the transmission path P2. The control terminal of the switch element SW2 is coupled to the controller 250. The impedance matching circuit 260_2 includes variable impedance circuits 261_2 to 263_2. Each of the variable impedance circuits 261_2 to 263_2 includes at least one of a variable resistor, a variable capacitor, and a variable inductor. The variable impedance circuits 261_2 to 263_2 are respectively electrically connected between the second terminal of the switch element SW2 and the reference low voltage.

The switch element SW2 may be turned on or turned off according to the switch control signal SSW2. The variable impedance circuit 261_2 may adjust its impedance value according to the voltage value of the impedance control signal SZ1_2. The variable impedance circuit 262_2 may adjust its impedance value according to the voltage value of the impedance control signal SZ2_2. The variable impedance circuit 263_2 may adjust its impedance value according to the voltage value of the impedance control signal SZ3_2.

In this embodiment, the detectors 240_1 and 240_2 are connected to the couplers 230_1 and 230_2 in a one-to-one manner, which should however not be construed as a limitation in the disclosure. In some embodiments, the detector 240_1 may be connected to at least the couplers 230_1 and 230_2 (as shown in FIG. 1). For instance, the detector 240_1 may also transmit the third input coupling signal SIN3 and the fourth input coupling signal SIN4 to the coupler 230_2 and receive the third coupling output signal SR3 and the fourth coupling output signal SR4 from the coupler 230_2. The detector 240_1 may also generate the second determination signal SD2 according to the third coupling output signal SR3 and the fourth coupling output signal SR4 and provide the second determination signal SD2 to the controller 250.

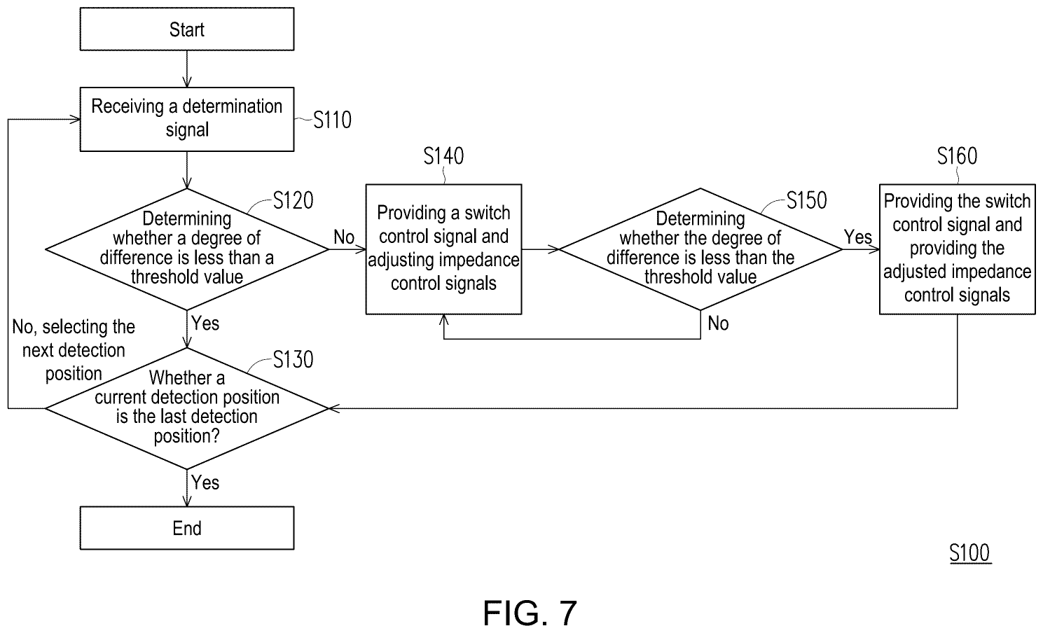

Please refer to FIG. 6 and FIG. 7. FIG. 7 is a flowchart illustrating an operation process according to an embodiment of the disclosure. In this embodiment, the operation process S100 includes steps S110 to S160. In step S110, the controller 250 receives a determination signal (e.g., the first determination signal SD1) from a detector (e.g., the detector 240_1), and in step S120, determines whether the degree of difference between two coupling output signals received by the detector (e.g., the degree of difference between the first coupling output signal SR1 and the second coupling output signal SR2 received by the detector 240_1) is less than a threshold value VT according to the determination signal (e.g., the first determination signal SD1). When the degree of difference is less than the threshold value VT, the controller 250 determines in step S130 whether a current detection position (e.g., a range detected by the detector) is the last detection position. If the current detection position is the last detection position, the operation process S100 ends. If the current detection position is not the last detection position, the next detection position is selected, and the operation returns to step S110.

In step S120, when the degree of difference is greater than or equal to the threshold value VT, the controller 250 provides the switch control signal SSW1 and adjusts the impedance control signals SZ1_1 to SZ3_1 in step S140, and then determines again whether the degree of difference is less than the threshold value VT in step S150. If the degree of difference is still greater than or equal to the threshold value VT, the controller 250 provides the switch control signal SSW1 again and adjust the impedance control signals SZ1_1 to SZ3_1 different from the previous ones in step S140. When the degree of difference is less than the threshold value VT, it indicates that the previous adjustment has achieved impedance match in the transmission path P1. Therefore, the controller 250 provides the switch control signal SSW1 and provides the adjusted impedance control signals SZ1_1 to SZ3_1 in step S160. Next, the controller 250 enters step S130.

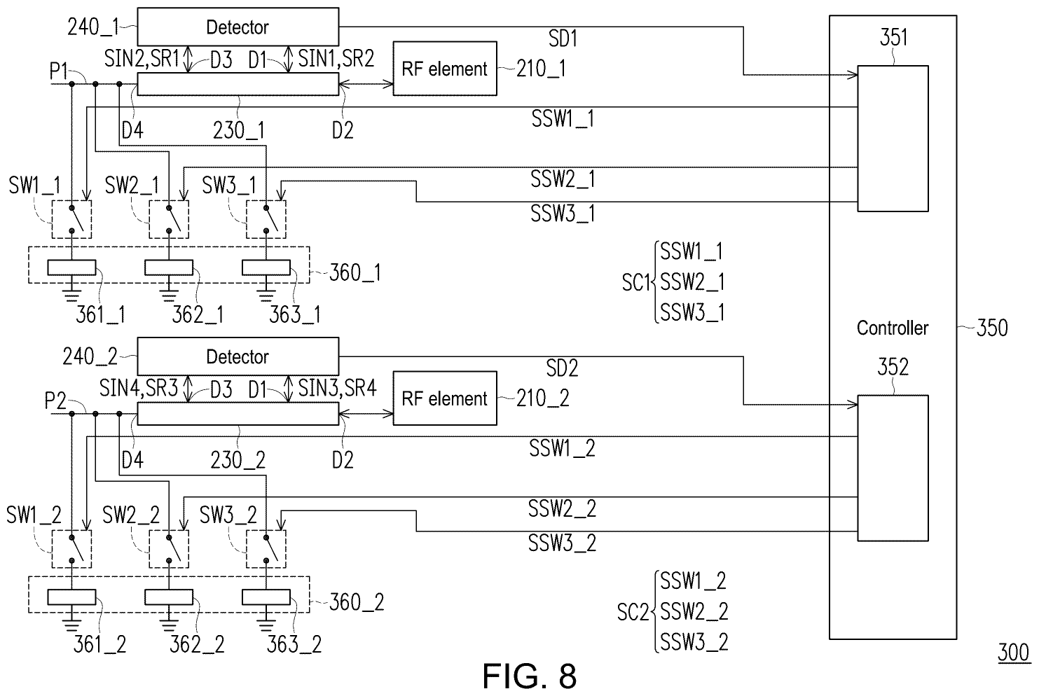

Please refer to FIG. 8, which is a schematic diagram illustrating an electronic device according to an embodiment of the disclosure. In this embodiment, a partial circuit of the electronic device 300 is provided. The electronic device 300 provided in this embodiment includes the substrate SB, the RF elements 210_1 and 210_2, the couplers 230_1 and 230_2, the detectors 240_1 and 240_2, a controller 350, impedance matching circuits 360_1 and 360_2, and switch elements SW1_1 to SW3_1 and SW1_2 to SW3_2. The operations of the RF elements 210_1 and 210_2, the couplers 230_1 and 230_2, and the detectors 240_1 and 240_2 in this embodiment have been clearly explained in the embodiment depicted in FIG. 6 and thus will not be repetitively described hereinafter.

In this embodiment, the controller 350 generates the first control signal SC1 according to the first determination signal SD1 and generates the second control signal SC2 according to the second determination signal SD2. The first control signal SC1 includes switch control signals SSW1_1 to SSW3_1. The second control signal SC2 includes switch control signals SSW1_2 to SSW3_2.

The first terminals of the switch elements SW1_1 to SW3_1 are electrically connected to the transmission path P1. The control terminals of the switch elements SW1_1 to SW3_1 are coupled to the controller 350. The impedance matching circuit 360_1 includes impedance circuits 361_1 to 363_1. The impedance circuit 361_1 is electrically connected between the second terminal of the switch element SW1_1 and the reference low voltage. The impedance circuit 362_1 is electrically connected between the second terminal of the switch element SW2_1 and the reference low voltage. The impedance circuit 363_1 is electrically connected between the second terminal of the switch element SW3_1 and the reference low voltage. The switch element SW1_1 may be turned on or turned off according to the switch control signal SSW1_1. The switch element SW2_1 may be turned on or turned off according to the switch control signal SSW2_1. The switch element SW3_1 may be turned on or turned off according to the switch control signal SSW3_1.

The first terminals of the switch elements SW1_2 to SW3_2 are electrically connected to the transmission path P2. The control terminals of the switch elements SW1_2 to SW3_2 are coupled to the controller 350. The impedance matching circuit 360_2 includes impedance circuits 361_2 to 363_2. The impedance circuit 361_2 is electrically connected between the second terminal of the switch element SW1_2 and the reference low voltage. The impedance circuit 362_2 is electrically connected between the second terminal of the switch element SW2_2 and the reference low voltage. The impedance circuit 363_2 is electrically connected between the second terminal of the switch element SW3_2 and the reference low voltage. The switch element SW1_2 may be turned on or turned off according to the switch control signal SSW1_2. The switch element SW2_2 may be turned on or turned off according to the switch control signal SSW2_2. The switch element SW3_2 may be turned on or turned off according to the switch control signal SSW3_2.

In some embodiments, the impedance circuits 361_1 to 363_1 and 361_2 to 363_2 respectively include at least one of a resistor, a capacitor, and an inductor. In some embodiments, the impedance circuits 361_1 to 363_1 and 361_2 to 363_2 respectively include at least two of the resistor, the capacitor, and the inductor. At least two of the resistor, the capacitor, and the inductor are, for instance, connected to each other in parallel or serially connected.

In this embodiment, the controller 350 includes look-up tables 351 and 352. The look-up table 351 provides the switch control signals SSW1_1 to SSW3_1 of the first control signal SC1 according to the first determination signal SD1. The look-up table 352 provides the switch control signals SSW1_2 to SSW3_2 of the second control signal SC2 according to the second determination signal SD2.

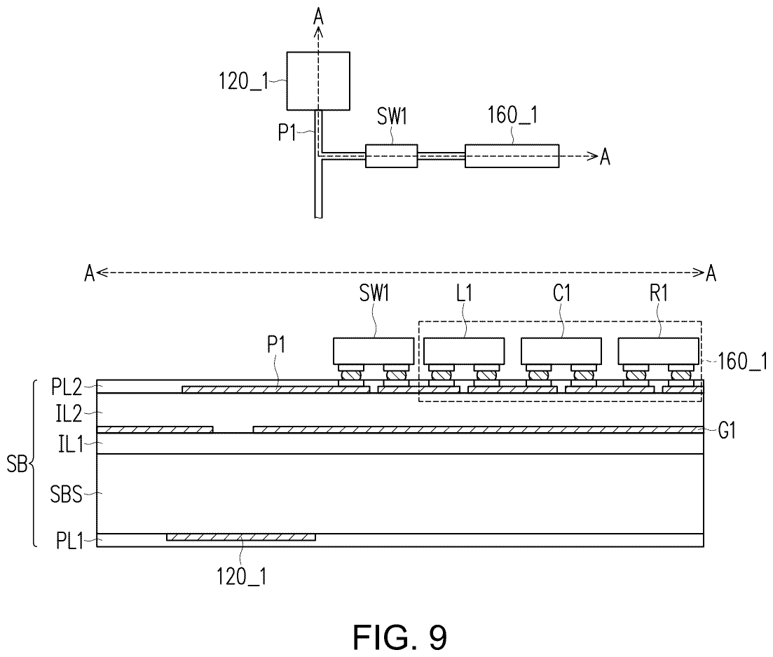

Please refer to FIG. 9. FIG. 9 is a schematic diagram illustrating an electronic element, an impedance matching circuit, and a switch element according to an embodiment of the disclosure. FIG. 9 illustrates a cross-sectional view along a sectional line AA. In this embodiment, the substrate SB includes a substrate main body SBS, protection layers PL1 and PL2, and insulation layers IL1 and IL2. The electronic element 120_1 is arranged on a first surface of the substrate main body SBS and is covered by the protection layer PL1. The insulation layer IL1 covers a second surface of the substrate main body SBS. The second surface is opposite to the first surface. A ground connection line G1 is arranged on the insulation layer IL1 and is covered by the insulation layer IL2. The transmission path P1 is arranged on the insulation layer IL2. The protection layer PL2 covers the insulation layer IL2 and at least one portion of the transmission path P1.

In this embodiment, the first terminal of the switch element SW1 may be electrically connected to the transmission path P1 on the insulation layer IL3 using a surface mount technology, for instance. The impedance matching circuit 160_1 includes the inductor L1, the capacitor C1, and the resistor R1. The inductor L1, the capacitor C1, and the resistor R1 may be serially connected to one another between the second terminal of the switch element SW1 and the reference low voltage using the surface mount technology, for instance. The switch element SW1, the inductor L1, the capacitor C1, and the resistor R1 are surface mount devices (SMD), respectively.

Moreover, the electronic element 120_1 may be electrically connected to the first terminal of the switch element SW1 through via structures (not shown) and/or connection structures (not shown) between the insulation layers IL1 to IL3.

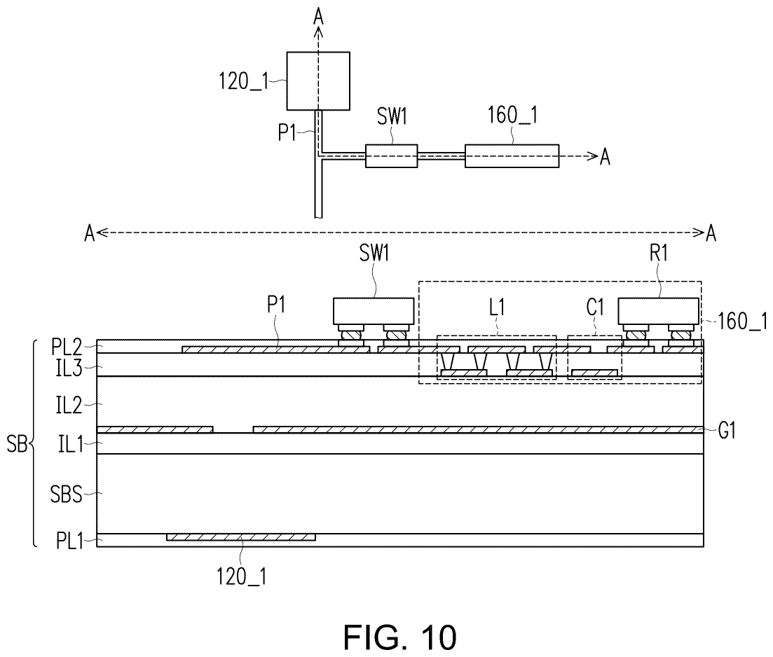

Please refer to FIG. 10. FIG. 10 is a schematic diagram illustrating an electronic element, an impedance matching circuit, and a switch element according to an embodiment of the disclosure. FIG. 10 illustrates a cross-sectional view along the sectional line AA. Different from the substrate SB shown in FIG. 9, the substrate SB in FIG. 10 further includes an insulation layer IL3. The insulation layer IL3 covers the insulation layer IL2 and is covered by the protection layer PL2. In this embodiment, the inductor L1 and the capacitor C1 are fabricated on the insulation layer IL3 using an integrated passive technology.

In some embodiments, the resistor R1 may be fabricated on the insulation layer IL3 using the integrated passive technology and covered by the protection layer PL2. In some embodiments, the switch element SW1 may be fabricated on the insulation layer IL3 using the integrated passive technology and covered by the protection layer PL2.

To sum up, the electronic device provided in one or more embodiments of the disclosure includes at least the RF element, the first electronic element, the first coupler, the detector, the controller, and the first impedance matching circuit. The electronic device generates the determination signal according to the first coupling output signal and the second coupling output signal and generates the control signal according to the determination signal. Therefore, the first impedance matching circuit provides the impedance for the transmission path between the RF element and the first electronic element in response to the control signal. As a result, the impedance for the transmission path between the RF element and the first electronic element may be matched.

Finally, note that the above embodiments simply serve to illustrate, but not to limit, the technical solutions of the disclosure. Although the disclosure has been described in detail with reference to the above embodiments, persons skilled in the art should understand that the technical solutions described in the above embodiments can still be modified or some or all of the technical features thereof can be equivalently replaced. However, the modifications or replacements do not cause the essence of the corresponding technical solutions to deviate from the scope of the technical solutions of the embodiments of the disclosure.

What is claimed is:

1. An electronic device, comprising:
a substrate;
a radio frequency element, arranged on the substrate;
a first electronic element, arranged on the substrate and electrically connected to the radio frequency element;
a first coupler, arranged on the substrate and configured to generate a first coupling output signal in response to a first input coupling signal and generate a second coupling output signal in response to a second input coupling signal;
a detector, arranged on the substrate, electrically connected to the first coupler, and configured to generate a first determination signal according to the first coupling output signal and the second coupling output signal;
a controller, arranged outside the substrate, electrically connected to the detector, and configured to generate a first control signal according to the first determination signal; and
a first impedance matching circuit, arranged on the substrate, electrically connected to the controller, and configured to provide an impedance for a transmission path between the radio frequency element and the first electronic element in response to the first control signal.

2. The electronic device according to claim 1, wherein during a first matching period, the first coupler receives the first input coupling signal and performs current dividing on the first input coupling signal to generate the first coupling output signal and a first coupling signal.

3. The electronic device according to claim 2, wherein the first coupler comprises:
a first connection point, electrically connected to the detector;
a second connection point, electrically connected to the detector; and
a third connection point, electrically connected to the first electronic element.

4. The electronic device according to claim 3, wherein the first coupler receives the first input coupling signal through the first connection point, provides the first coupling output signal to the detector through the second connection point, and provides the first coupling signal to the first electronic element through the third connection point.

5. The electronic device according to claim 3, wherein a numerical value of the first coupling output signal reflects an impedance ratio at the second connection point and the third connection point.

6. The electronic device according to claim 3, wherein during a second matching period, the first coupler receives the second input coupling signal and performs current dividing on the second input coupling signal to generate the second coupling output signal and a second coupling signal.

7. The electronic device according to claim 6, wherein the first coupler comprises:
a fourth connection point, electrically connected to the radio frequency element.

8. The electronic device according to claim 7, wherein the first coupler receives the second input coupling signal through the second connection point, provides the second coupling output signal to the detector through the first connection point, and provides the second coupling signal to the radio frequency element through the fourth connection point.

9. The electronic device according to claim 8, wherein a numerical value of the second coupling output signal reflects an impedance ratio at the first connection point and the fourth connection point.

10. The electronic device according to claim 1, wherein the first electronic element is one of an antenna element and a power divider.

11. The electronic device according to claim 1, further comprising:
a second electronic element, arranged on the substrate;
a second coupler, arranged on the substrate, electrically connected to the detector, and configured to generate a third coupling output signal in response to a third input coupling signal and generate a fourth coupling output signal in response to a fourth input coupling signal.

12. The electronic device according to claim 11, wherein during a third matching period, the second coupler receives the third input coupling signal and performs current dividing on the third input coupling signal to generate the third coupling output signal and a third coupling signal.

13. The electronic device according to claim 11, wherein during a fourth matching period, the second coupler receives the fourth input coupling signal and performs current dividing on the fourth input coupling signal to generate the fourth coupling output signal and a fourth coupling signal.

14. The electronic device according to claim 11, wherein the detector generates a second determination signal according to the third coupling output signal and the fourth coupling output signal.

15. The electronic device according to claim 14, wherein the controller generates a second control signal according to the second determination signal.

16. The electronic device according to claim 15, further comprising:
a second impedance matching circuit, arranged on the substrate, electrically connected to the controller, and configured to provide an impedance for a transmission path between the radio frequency element and the second electronic element in response to the second control signal.

17. The electronic device according to claim 1, further comprising:
a switch element, arranged on the substrate, wherein a first terminal of the first impedance matching circuit is electrically connected to the first electronic element and the radio frequency element through the switch element.

18. The electronic device according to claim 17, wherein a second terminal of the first impedance matching circuit is electrically connected to a reference low voltage.

19. The electronic device according to claim 1, wherein when the first determination signal is greater than a threshold value, the controller changes the first control signal, so that the first impedance matching circuit changes the impedance for the transmission path between the radio frequency element and the first electronic element according to the first control signal.

20. The electronic device according to claim 1, wherein the first impedance matching circuit changes at least one of a resistance, a capacitance, and an inductance of the first impedance matching circuit in response to the first control signal.
